(19) United States
(12) Patent Application Publication
(10) Pub. No.: US 2026/0046521 A1
(43) Pub. Date: Feb. 12, 2026

(54) ELECTRONIC DEVICE INCLUDING CAMERA, METHOD OF CAPTURING IMAGE IN THE ELECTRONIC DEVICE, AND NON-TRANSITORY STORAGE MEDIUM

(71) Applicant: Samsung Electronics Co., Ltd., Suwon-si (KR)

(72) Inventors: Sangbum JEONG, Suwon-si (KR); Jaehyoung PARK, Suwon-si (KR); Jonghoon WON, Suwon-si (KR)

(21) Appl. No.: 19/297,795

(22) Filed: Aug. 12, 2025

Related U.S. Application Data
(63) Continuation of application No. PCT/KR2025/012172, filed on Aug. 12, 2025.

(30) Foreign Application Priority Data
Aug. 12, 2024 (KR) 10-2024-0107715
Feb. 17, 2025 (KR) 10-2025-0020264

(51) Int. Cl. H04N 23/68; H04N 23/69; H10F 39/00

(52) U.S. Cl. CPC H04N 23/687; H04N 23/69; H10F 39/8063

(57) ABSTRACT

The disclosure relates to an electronic device including a camera, a method of capturing an image in the electronic device, and a non-transitory storage medium. The electronic device may obtain an image corresponding to a subject using an image sensor included in a camera assembly of the electronic device, obtain, from memory of the electronic device, pre-specified shading correction data for shading correction of a first region of interest (ROI) specified within the image, based on the shading correction data, identify a movement position of the image sensor to correct a shading deviation between first sub-photodiodes corresponding respectively to a plurality of first micro lenses arranged in a first area corresponding to the first ROI in an image height of the image sensor, based on the movement position, control an actuator included in an image stabilizer of the camera assembly to move a position of the image sensor, and obtain, using the image sensor, first image data of the first ROI in which the shading deviation between the first sub-photodiodes is corrected.

### CROSS-REFERENCE TO RELATED APPLICATIONS

This application is a continuation of International Application No. PCT/KR2025/012172 designating the United States, filed on Aug. 12, 2025, in the Korean Intellectual Property Receiving Office and claiming priority to Korean Patent Application Nos. 10-2024-0107715, filed on Aug. 12, 2024, and 10-2025-0020264, filed on Feb. 17, 2025, in the Korean Intellectual Property Office, the disclosures of each of which are incorporated by reference herein in their entireties.

### BACKGROUND

### Field

The disclosure relates to an electronic device including a camera, a method of capturing an image in the electronic device, and a non-transitory storage medium.

### Description of Related Art

Various services and additional functions provided through electronic devices, for example, portable electronic devices such as smartphones, are gradually increasing. In order to increase the utility of these electronic devices and satisfy the needs of various users, communication service providers or electronic device manufacturers are competitively developing electronic devices to provide various functions and differentiate themselves from other companies. Accordingly, various functions provided through electronic devices are also becoming more sophisticated.

Recently, electronic devices include high-performance cameras, and technologies for capturing high-quality images in various ways are under development. A camera may include an image sensor that detects an object. An electronic device may detect an object or an image through an image sensor. The image sensor may include a plurality of pixel units, and each pixel unit may include a plurality of sub-pixels. The image sensor may include an array of small photodiodes called pixels or photosites.

As the technology of cameras included in electronic devices has developed, focus control or hand shake correction functions have been provided to improve focus detection performance and image quality through image stabilization, when an image is captured.

The above information is presented as prior art only to assist with an understanding of the disclosure. No determination has been made, and no assertion is made, as to whether any of the above might be applicable as prior art with regard to the disclosure.

Due to limitations in the design and manufacturing process of an image sensor of a camera included in an electronic device, the chief ray angle (CRA) of light that does not cause shading on a pixel (e.g., unit pixel), which is in a viewing direction of a micro lens disposed directly on a photodiode, is fixed. Therefore, when a lens and the micro lens are not aligned to the CRA in various capturing environments, a CRA error may occur. The electronic device applies a pixel-by-pixel correction coefficient to correct the error, which causes a larger photodiode (PD) shading error in some area (e.g., an edge) of an image height of the image sensor. In this case, since a gain for correcting the shading also increases, shading may deteriorate remosaic quality or focus (auto focus (AF)) performance, and image quality may be deteriorated.

### SUMMARY

According to an example embodiment of the disclosure, an electronic device includes: a display, a camera assembly including camera circuitry, at least one processor comprising processing circuitry, and memory storing instructions.

According to an example embodiment, the camera assembly may include a lens, an image sensor configured to provide an electric signal corresponding to light received through the lens, and an image stabilizer including an actuator configured to move at least one of the lens or the image sensor for image stabilization.

According to an example embodiment, the image sensor includes a plurality of unit photodiodes, each including a plurality of sub-photodiodes, and a plurality of micro lenses corresponding to the plurality of unit photodiodes, respectively. The plurality of sub-photodiodes included in one unit photodiode correspond to one micro lens.

According to an example embodiment, the instructions, when executed by the at least one processor individually or collectively, cause the electronic device to obtain an image corresponding to a subject using the image sensor.

According to an example embodiment, the instructions, when executed by the at least one processor individually or collectively, cause the electronic device to: obtain, from the memory, specified shading correction data for shading correction of a first region of interest (ROI) specified within the image. The shading correction data includes position information set to match a chief ray angle (CRA) of the image sensor or a CRA of the lens to a specified CRA

According to an example embodiment, the instructions, when executed by the at least one processor individually or collectively, cause the electronic device to,: based on the shading correction data, identify a movement position of the image sensor to correct a shading deviation between first sub-photodiodes corresponding respectively to a plurality of first micro lenses arranged in a first area corresponding to the first ROI in an image height of the image sensor.

According to an example embodiment, the instructions, when executed by the at least one processor individually or collectively, cause the electronic device to, based on the movement position, control the actuator to move a position of the image sensor.

According to an example embodiment, the instructions, when executed by the at least one processor individually or collectively, cause the electronic device to obtain, using the image sensor, first image data of the first ROI in which the shading deviation between the first sub-photodiodes is corrected.

According to an example embodiment of the disclosure, an electronic device includes a display, a camera assembly including camera circuitry, at least one processor, comprising processing circuitry, and memory storing instructions.

According to an example embodiment, the camera assembly includes a lens, an image sensor configured to provide an electric signal corresponding to light received through the lens, and an image stabilizer including an actuator configured to move at least one of the lens or the image sensor for image stabilization.

According to an example embodiment, the image sensor includes a plurality of unit photodiodes, each including a plurality of sub-photodiodes, and a plurality of micro lenses corresponding to the plurality of unit photodiodes, respectively.

According to an example embodiment, the instructions, when executed by the at least one processor individually or collectively, cause the electronic device to obtain an image corresponding to a subject using the image sensor.

According to an example embodiment, the instructions, when executed by the at least one processor individually or collectively, cause the electronic device to obtain, from the memory, specified shading correction data for shading correction of a first ROI specified within the image.

According to an example embodiment, the shading correction data includes position information set to match a chief ray angle (CRA) of the image sensor or a CRA of the lens to a specified CRA.

According to an example embodiment, the instructions, when executed by the at least one processor individually or collectively, cause the electronic device to: based on the shading correction data, identify a target movement position of the lens to correct a shading deviation between first sub-photodiodes corresponding respectively to a plurality of first micro lenses arranged in a first area corresponding to the first ROI in an image height of the image sensor.

According to an example embodiment, the instructions, when executed by the at least one processor individually or collectively, cause the electronic device to, based on the target movement position of the lens, control the actuator to move a position of the lens.

According to an example embodiment, the instructions, when executed by the at least one processor individually or collectively, cause the electronic device to obtain, using the image sensor, second image data of the first ROI in which the shading deviation is corrected by the movement of the lens.

According to an example embodiment, a method of operating an electronic device may include: obtaining an image corresponding to a subject using an image sensor included in a camera assembly of the electronic device.

According to an example embodiment, the method may include obtaining, from memory of the electronic device, specified shading correction data for shading correction of a first ROI specified within the image. According to an example embodiment, the shading correction data includes position information set to match a chief ray angle (CRA) of the image sensor or a CRA of a lens to a specified CRA.

According to an example embodiment, the method may include, based on the shading correction data, identifying a movement position of the image sensor to correct a shading deviation between first sub-photodiodes corresponding respectively to a plurality of first micro lenses arranged in a first area corresponding to the first ROI in an image height of the image sensor.

According to an example embodiment, the method may include, based on the movement position, controlling an actuator included in an image stabilizer of the camera assembly to move a position of the image sensor.

According to an example embodiment, the method may include obtaining, using the image sensor, first image data of the first ROI in which the shading deviation between the first sub-photodiodes is corrected.

According to an example embodiment, in a non-transitory computer-readable storage medium storing at least one program, the at least one program may include instructions that, when executed by at least one processor, comprising processing circuitry, individually and/or collectively, of an electronic device, may cause the electronic device to obtain an image corresponding to a subject using an image sensor included in a camera assembly of the electronic device.

According to an embodiment, the at least one program may include instructions that, when executed by at least one processor of the electronic device, cause the electronic device to obtain, from memory of the electronic device, pre-specified shading correction data for shading correction of a first ROI specified within the image. The shading correction data may include position information set to match a CRA of the image sensor or a CRA of a lens to a specified CRA.

According to an example embodiment, the at least one program may include instructions that, when executed by at least one processor of the electronic device, cause the electronic device to, based on the shading correction data, identifying a movement position of the image sensor to correct a shading deviation between first sub-photodiodes corresponding respectively to a plurality of first micro lenses arranged in a first area corresponding to the first ROI in an image height of the image sensor.

According to an example embodiment, the at least one program may include instructions that, when executed by at least one processor of the electronic device, cause the electronic device to, based on the movement position, controlling an actuator included in an image stabilizer of the camera assembly to move a position of the image sensor.

According to an example embodiment, the at least one program may include instructions that, when executed by the at least one processor of the electronic device, cause the electronic device to obtain, using the image sensor, first image data of the first ROI in which the shading deviation between the first sub-photodiodes is corrected.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a diagram illustrating an example configuration of camera circuitry in an electronic device according to an embodiment.

FIG. 3 is a diagram illustrating an example configuration of an electronic device that outputs image data according to an embodiment.

FIG. 4A is a diagram illustrating an example structure of an image sensor having two photodiodes, and a lens according to an embodiment.

FIG. 4B is a diagram illustrating an example structure of a unit pixel having two photodiodes according to an embodiment.

FIG. 4C is a diagram illustrating an example structure of a unit pixel having four photodiodes according to an embodiment.

FIG. 5 is a diagram illustrating an example of shading correction in an electronic device according to an embodiment.

FIG. 6A is a diagram illustrating an example image sensor of camera circuitry according to an embodiment.

FIG. 6B is an example lookup table including shading correction data according to an embodiment.

FIG. 7 is a diagram illustrating an example of CRA alignment in camera circuitry of an electronic device according to an embodiment.

FIG. 8 is a diagram illustrating an example sensor shift operation in camera circuitry of an electronic device according to an embodiment.

FIG. 9 is a diagram illustrating an example lens shift operation in camera circuitry of an electronic device according to an embodiment.

FIG. 10 is a flowchart illustrating an example method of operating an electronic device according to an embodiment.

FIG. 11 is a diagram illustrating an example of shading correction in an example method of operating an electronic device according to an embodiment.

FIG. 12 is a diagram illustrating an example of shading correction according to an embodiment.

In relation to the description of the drawings, the same or similar reference numerals may be used for the same or similar components.

### DETAILED DESCRIPTION

Various example embodiments of the disclosure will be described in greater detail below in with reference to the drawings. However, the disclosure may be implemented in various different forms and is not limited to the various embodiments described herein. In connection with the description of the drawings, the same or similar reference numerals may be used for the same or similar components. Further, in the drawings and related descriptions, a description of well-known functions and configurations may be avoided for clarity and conciseness. The term “user” used in the disclosure, may refer to a person using an electronic device or a device (e.g., an artificial intelligent electronic device) using an electronic device.

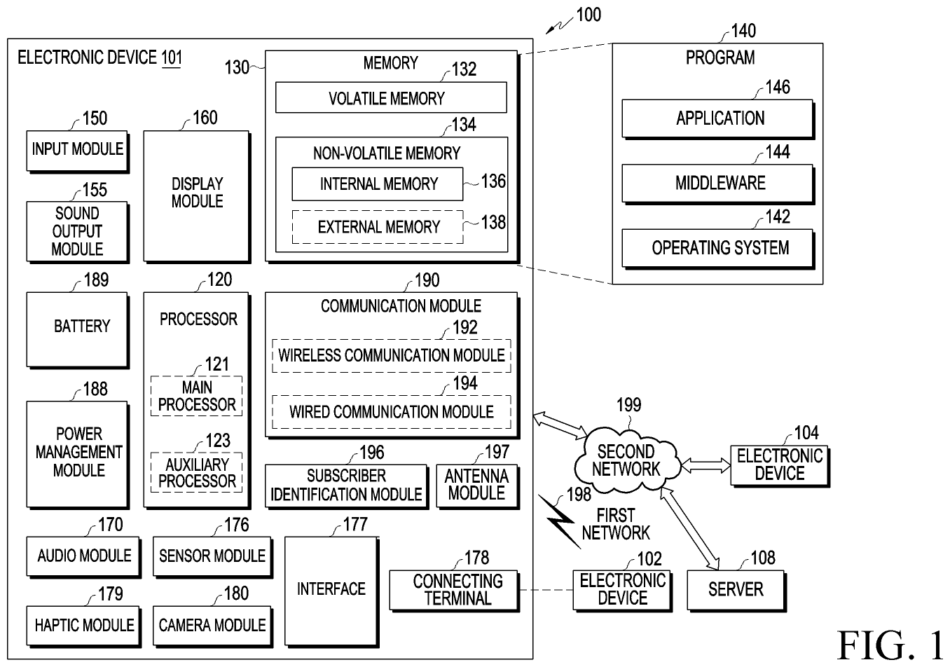

FIG. 1 is a block diagram illustrating an example electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121. Thus, the processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited /isclosed functions, e.g., in a distributed manner. At least one processor may execute program instructions to achieve or perform various functions.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the strength of force incurred by the touch.

The audio module 170 may convert a sound into an electric signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electric signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electric signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beamforming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form an mmWave antenna module. According to an embodiment, the mmWave antenna module may include a printed circuit board, a RFIC disposed on a first surface (e.g., the bottom surface) of the printed circuit board, or adjacent to the first surface and capable of supporting a specified high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the specified high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

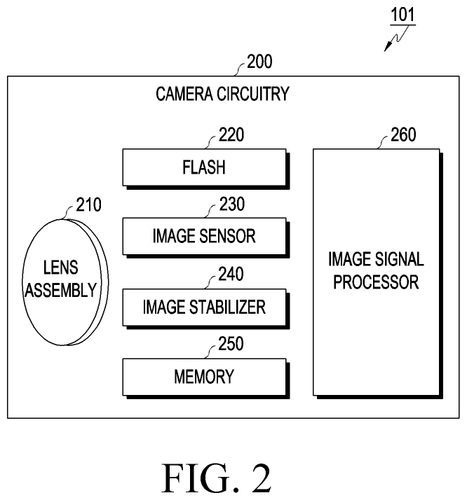

FIG. 2 is a diagram illustrating an example configuration of camera circuitry in an electronic device according to an embodiment.

Referring to FIGS. 1 and 2, the electronic device 101 according to an embodiment may include the processor (e.g., including processing circuitry) 120, the memory 130, the display 160, and camera circuitry 200 (e.g., the camera module 180 of FIG. 1 or a camera assembly). The electronic device 101 may further include other components illustrated in FIG. 1.

An operation of the electronic device 101 according to an embodiment may be controlled by the processor 120 (e.g., the processor 120 of FIG. 1 and/or an image signal processor 260 of FIG. 2) of the electronic device 101. Performing a specific operation by the electronic device 101 may amount to controlling the electronic device 101 or a component included in the electronic device 101 by the processor 120 of the electronic device 101. The electronic device 101 may include one or more processors 120, and even when a plurality of processors 120 are implemented, the term “operation of the electronic device 101” or “operation of the processor 120”will be used hereinbelow, for convenience of description.

According to an embodiment, the processor 120 of the electronic device 101 may control to process an image captured by the camera circuitry 200 and output the image to the display 160. The processor 120 of the electronic device 101 may include the image signal processor 260 illustrated in FIG. 2 or control a processing operation of the image signal processor 260.

According to an embodiment, the camera assembly of the electronic device 101 (e.g., the electronic device 101 of FIG. 1) may include the camera circuitry 200 (e.g., the camera module 180 of FIG. 1). The camera assembly may include a lens assembly (e.g., including at least one lens) 210, a flash 220, an image sensor 230, an image stabilizer (e.g., including various circuitry) 240, memory 250 (e.g., a buffer memory), and/or the image signal processor (e.g., including circuitry) 260. The lens assembly 210 may collect light emitted from a subject that is a target for image capturing. The lens assembly 210 may include one or more lenses. According to an embodiment, the camera circuitry 200 may include a plurality of lens assemblies 210. In this case, the camera circuitry 200 may form, for example, a dual camera, a 360-degree camera, or a spherical camera. Some of the plurality of lens assemblies 210 may have the same lens properties (e.g., angle of view, focal length, autofocus, f number, or optical zoom), or at least one lens assembly may have one or more lens properties different from those of another lens assembly. The lens assembly 210 may include, for example, a wide-angle lens or a telephoto lens.

According to an embodiment, the flash 220 may emit light used to enhance light emitted or reflected from a subject. According to an embodiment, the flash 220 may include one or more light emitting diodes (e.g., red-green-blue (RGB) LEDs, white LEDs, infrared LEDs, or ultraviolet LEDs) or a xenon lamp.

According to an embodiment, the image sensor 230 may convert the light emitted or reflected from the subject and transmitted through the lens assembly 210 into an electric signal, thereby obtaining an image (e.g., a Bayer image or raw image data) corresponding to the subject. According to an embodiment, the image sensor 230 may include one image sensor selected from among image sensors having different properties, such as an RGB sensor, a black and white (BW) sensor, an IR sensor, or a UV sensor, a plurality of image sensors having the same properties, or a plurality of image sensors having different properties. Each image sensor included in the image sensor 230 may be implemented using, for example, a charged coupled device (CCD) sensor or a complementary metal oxide semiconductor (CMOS) sensor.

According to an embodiment, the image stabilizer 240 may include various circuitry and move at least one lens included in the lens assembly 210 or the image sensor 230 in a specific direction or control operation characteristics (e.g., adjust an exposure timing) of the image sensor 230 in response to the movement of the camera circuitry 200 or the electronic device 101 including the camera circuitry 200. This allows at least some of the negative effects of the movement on an image being captured to be compensated for. According to an embodiment, the image stabilizer 240 may detect the movement of the camera circuitry 200 or the electronic device 101, using a gyro sensor (not shown) or an acceleration sensor (not shown) disposed inside or outside the camera circuitry 200. According to an embodiment, the image stabilizer 240 may be implemented as, for example, an optical image stabilizer.

According to an embodiment, the memory 250 may temporarily store at least a portion of the image obtained through the image sensor 230 for a next image processing operation. According to an embodiment, the memory 250 may be configured as at least a portion of the memory 130 of FIG. 1 or as a separate memory that operates independently therefrom.

According to an embodiment, the image signal processor 260 may include various image processing circuitry and/or executable program instructions and perform one or more image processes for the image obtained through the image sensor 230 or the image stored in the memory 250. The one or more image processes may include, for example, depth map generation, 3D modeling, panorama generation, feature point extraction, image synthesis, or image compensation (e.g., noise reduction, resolution adjustment, brightness adjustment, blurring, sharpening, or softening). Additionally or alternatively, the image signal processor 260 may perform control (e.g., exposure time control or read-out timing control) for at least one (e.g., the image sensor 230) of the components included in the camera module 180. The image processed by the image signal processor 260 may be stored back in the memory 250 for further processing or provided to a component (e.g., the memory 130, the display module 160, the electronic device 102, the electronic device 104, or the server 108) external to the camera module 180. According to an embodiment, the image signal processor 260 may be configured as at least a portion of the processor 120 of FIG. 1 or as a separate processor that operates independently from the processor 120. When the image signal processor 260 is configured as a separate processor from the processor 120, at least one image processed by the image signal processor 260 may be displayed through the display module 160 as it is or after additional image processing by the processor 120.

According to an embodiment, the electronic device 101 may include a plurality of camera circuits each having different properties or functions. In this case, for example, at least one of the plurality of camera circuits may be a wide-angle camera and at least another one of them may be a telephoto camera. At least one of the plurality of camera circuits may be a front camera and at least another one of them may be a rear camera.

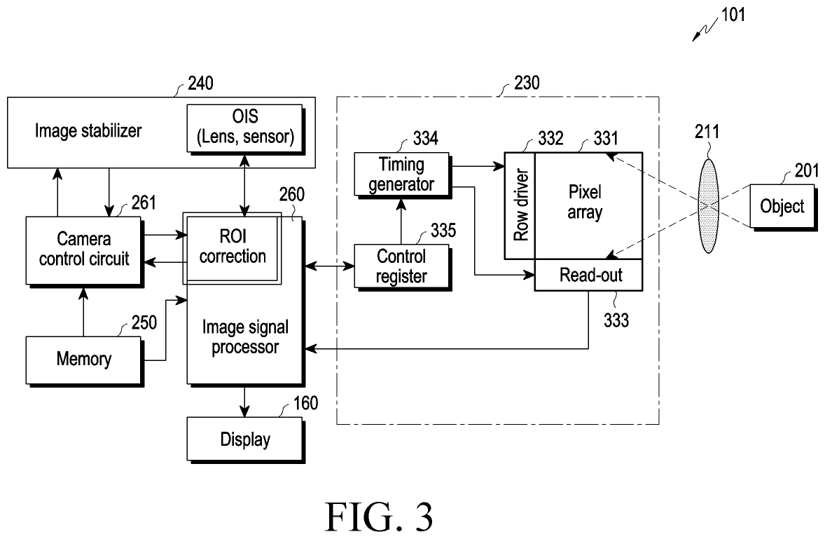

FIG. 3 is a diagram illustrating an example configuration of an electronic device that outputs image data according to an embodiment.

Referring to FIG. 3, according to an embodiment, a lens 211 may include a photographing lens. The lens 211 may be implemented in a size corresponding to, for example, a pixel array 331, and configured to form an image of an object 201.

According to an embodiment, the image sensor 230 may be operatively connected to the image signal processor 260 (e.g., the processor 120 of FIG. 1 and the image signal processor 260 of FIG. 2), and obtain image data (e.g., a Bayer image or raw data) corresponding to the object 201 by converting an optical signal introduced through the lens 211 into an electric signal under the control of the image signal processor 260. Herein, the “raw data” may refer, for example, to an image corresponding to data about the object 201 (e.g., a subject) obtained through the image sensor 230.

According to an embodiment, the image signal processor 260 may output the image data detected and generated by the image sensor 230 to the display 160. For example, the display 160 may be implemented as a dedicated display such as a monitor or a display formed on an electronic device such as a computer, a mobile phone, a TV, or a camera. The image sensor 230 is described as an image sensor and a component of a camera, for convenience of description, to which the image sensor 230 is not limited, and various modifications are possible.

According to an embodiment, the image sensor 230 may include the pixel array 331 including a plurality of unit pixels, a row driver 332 controlling the pixel array 331 on a row basis, a read-out 333 outputting a signal from the pixel array 331, a timing generator 334 providing a clock signal to the row driver 332 and the read-out 333, and/or a control register 335 storing various commands required for the operation of the image sensor 230. The image sensor 230 may output color information including information about at least one color of red (R), green (G), or blue (B). R may include, for example, red, and G may include, for example, green. In addition, B may include, for example, blue.

According to an embodiment, the pixel array 331 may include a plurality of unit pixels (e.g., unit photodiodes). Each unit pixel may include, for example, a plurality of sub-pixels (e.g., sub-photodiodes). Each unit pixel may include two sub-photodiodes or four sub-photodiodes. Each sub-pixel may sense light incident through the lens 211 under the control of the row driver 332 and output at least one sub-pixel signal.

According to an embodiment, the pixel array 331 may output a sub-pixel signal from a row selected by each control signal provided from the row driver 332 to the read-out 333. According to an embodiment, the pixel array 331 may output each sub-pixel-level signal on a row basis along a column line under the control of the timing generator 334.

According to an embodiment, the pixel array 331 may output as many sub-pixel signals as the product between a total number of unit pixels and the number of sub-pixels in each pixel at once or may output as many sums of sub-pixel-level signals in the respective unit pixels as the total number of unit pixels.

According to an embodiment, a filter array including a color filter for transmitting or blocking light of a specific spectrum region for each unit pixel may be arranged over the unit pixels forming the pixel array 331. Further, micro lenses may be arranged over the unit pixels forming the pixel array 331, respectively, to increase the light gathering power of the unit pixels.

According to an embodiment, the row driver 332 may drive control signals for controlling the operations of the plurality of respective sub-pixels to the pixel array 331 under the control of the timing generator 334. For example, the plurality of control signals may include a signal for controlling the transmission of photoelectric charges generated by each of the plurality of sub-pixels, a signal for selecting each of the plurality of sub-pixels, or a signal for resetting each of the plurality of sub-pixels.

According to an embodiment, the read-out 333 may include various components (e.g., a counter and memory (e.g., a plurality of column memories), a read-out circuit, or a sense amplifier (SA)) for processing a sub-pixel-level signal output from the pixel array 331. According to an embodiment, the read-out 333 may temporarily store a sub-pixel signal output from the pixel array 331 and then sense, amplify, and output the sub-pixel signal.

According to an embodiment, the read-out 333 may output a sub-pixel-level signal corresponding to each sub-pixel.

According to an embodiment, the timing generator 334 may output a control signal or a clock signal to each of the row driver 332 and/or the read-out 333 to control the timing of the row driver 332 and/or the read-out 333. The control register 335 may operate under the control of the processor 120 and store commands required for the operation of the image sensor 230.

According to an embodiment, the image signal processor 260 may process image data output from the image sensor 230. The image signal processor 260 may be one of multiple processors included in the electronic device 101. The image signal processor 260 described in the disclosure may be replaced with another processor that may process image data included in the electronic device 101.

According to an embodiment, the image signal processor 260 may process image data output from an R pixel, image data output from a B pixel, and image data output from a G pixel. The image signal processor 260 may process sub-pixel-level signals or unit pixel-based image data output from the read-out 333 on a sub-pixel basis or on a unit pixel basis.

According to an embodiment, the image sensor 230 may combine the respective sub-pixel-level signals of a unit pixel and output the combined signal as one image data. The image sensor 230 may output information for calculating a phase difference between the sub-pixels (e.g., sub-photodiodes) included in each unit pixel (e.g., unit photodiode), for example. For example, the unit pixel may also output information for calculating a phase difference between light entering the respective photodiodes, and output color information that is the sum of two sub-pixel-level (e.g., sub-photodiode) signals.

According to an embodiment, the image processing operation in the image sensor 230 may be implemented by a combination of at least one of software, firmware, or hardware. At least a portion of the processor 120 may include, for example, a module, a program, a routine, a set of instructions, or a process for performing one or more functions.

According to an embodiment, the electronic device 101 may be implemented by integrating, for example, a camera control circuit 261 and the image signal processor 260 with the processor (e.g., the processor 120 of FIG. 1), and may be implemented to be stored in a dedicated memory area accessible to the processor in the form of software and executable by the processor.

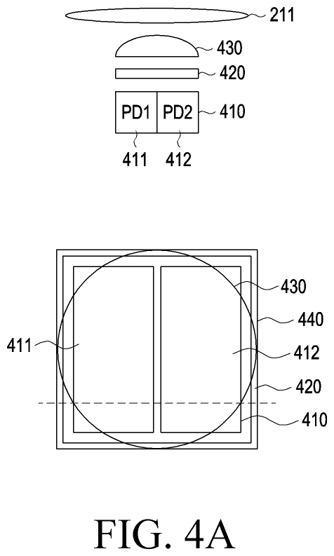

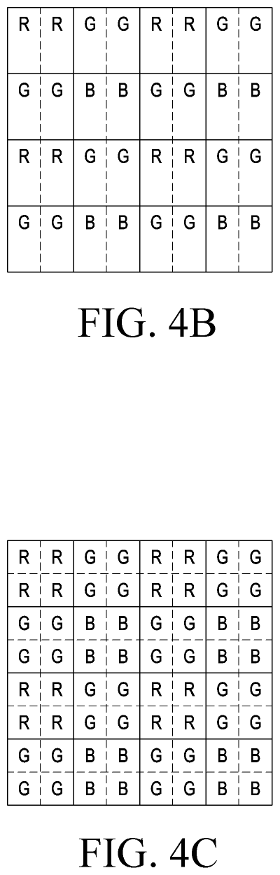

FIG. 4A is a diagram illustrating an example structure of an image sensor having two photodiodes corresponding to one micro lens, and a lens according to an embodiment, FIG. 4B is a diagram illustrating an example structure of a unit pixel having two photodiodes according to an embodiment, and FIG. 4C is a diagram illustrating an example structure of a unit pixel having four photodiodes according to an embodiment.

Referring to FIG. 3 and FIGS. 4A, 4B and 4C (which may be referred to as FIGS. 4A to 4C), when light enters a photoconductor through a color filter 420, the image sensor 230 according to an embodiment changes electrons-holes generated in the photoconductor according to the wavelength and intensity of the light, and output this as a voltage signal at a signal processable level. Such image sensors 230 may be classified into, for example, a charge coupled device (CCD)-type image sensor and a complementary metal oxide semiconductor (CMOS)-type image sensor depending on their methods. The image sensor 230 may form a plurality of unit pixels (e.g., unit photodiodes) 410, and an image sensor array with the plurality of unit pixels arranged in predetermined columns and rows may be used to obtain image data of a predetermined size.

According to an embodiment, the lens 211 may be operatively connected to the image stabilizer 240 including an actuator for image stabilization (e.g., optical image stabilization (OIS) or auto focus (AF)).

According to an embodiment, each of the unit pixels 410 in the image sensor 230 may include two sub-photodiodes 411 and 412, the color filter 420, and/or a micro lens 430. In addition, the unit pixel of the image sensor 230 may include, for example, four sub-photodiodes, the color filter 420, and/or the micro lens 430. The number of sub-pixels per unit pixel according to an embodiment may be any number. FIG. 4B illustrates a case in which each unit pixel includes two sub-pixels, and FIG. 4C illustrates a case in which each unit pixel includes four sub-pixels. Each unit pixel may detect a corresponding color by passing only light of the color through the color filter 420 of the red R, green G, or blue B color. As illustrated in FIGS. 4B and 4C, green may be disposed every two unit pixels, while blue and red may be disposed every four unit pixels. In addition to the configurations illustrated in FIGS. 4B and 4C, the unit pixels of the image sensor 230 may be configured in various manners, such as an Octa and a Nona configuration.

According to an embodiment, the image sensor 230 may include at least one color filter 420 among an R (e.g., red) filter, a G (e.g., green) filter, a B (e.g., blue) filter, a yellow filter, a magenta filter, a cyan filter, and a white filter. According to an embodiment, the color filter 420 may be formed on the unit photodiode 410 (e.g., unit pixel) including the sub-photodiodes PD1 and PD2 411 and 412 based on an incident angle of incident light, and have a Bayer pattern. For the Bayer pattern, filters may be arranged, which receive the brightness of each of red, green, and blue on a two-dimensional plane to collect brightness and colors of an object and create image data of points. Each of unit pixels forming a grid under the color filter of the Bayer pattern may recognize only an assigned color among red, green, and/or blue and interpolate it.

According to an embodiment, the micro lens 430 may be formed over the color filter 420 to correspond to the unit photodiode 410 including the sub-photodiodes 411 and 412. A barrier 440 may be located between photodiodes 410. For example, at least one color filter 420 may be located over a plurality of photodiodes 410. Further, for example, at least one micro lens 430 may be located over a plurality of unit photodiodes 410. The micro lens 430 may be located over the color filter 420, for example.

According to an embodiment, the sub-photodiodes PD1 and PD2 411 and 412 may receive light that has passed through the same micro lens 430. For example, each of the two sub-photodiodes 411 and 412 may receive light passing through a color filter area and generate a charge corresponding to the energy of the received light.

The image sensor 230 of the camera circuitry 200 of the electronic device 101 according to an embodiment may be designed such that the chief ray angle (CRA) of the image sensor 230 and the CRA of the lens 211 are matched to minimize and/or reduce a shading deviation between the plurality of sub-photodiodes 411 and 412, and the viewing direction (e.g., CRA) of the micro lens 430 of the image sensor 230 may be modified (e.g., micro lens shrink) according to each field divided in an image height. A CRA may refer, for example, to the upper limit of a light inflow angle at which no shading occurs in a pixel (e.g., unit pixel). The CRA state of the lens 211 may vary according to an AF operation. According to an embodiment, the electronic device 101 may perform an operation of correcting the shading deviation between the sub-photodiodes 411 and 412 in a region of interest (ROI).

According to an embodiment, since the CRA of the micro lens 430 of the aligned image sensor 230 is fixed, when the CRA of the lens 211 changes due to a focus adjustment operation, a zoom operation, or hand shaking of the lens 211, shading may increase due to a CRA alignment error of the plurality of photodiodes 410 caused by the change in the CRA of the lens 211 in the image height. According to an embodiment, the electronic device 101 may perform a shading correction operation of moving the image sensor 230 or the lens 211 using the image stabilizer 240 included in the camera circuitry 200 to reduce a shading deviation between pixels caused in ROIs (e.g., ROIs at an edge of an image) located in various image heights, thereby improving the CRA alignment accuracy and thus obtaining high focus detection performance and image quality.

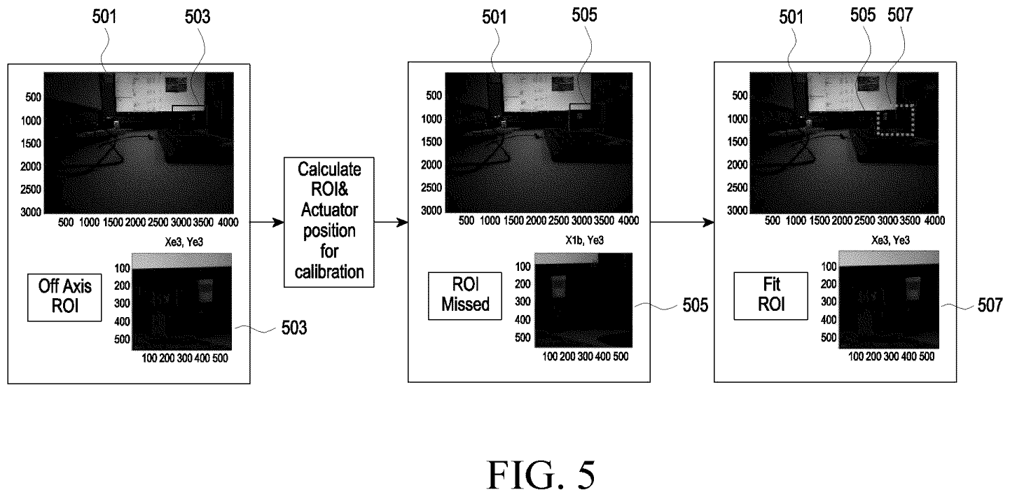

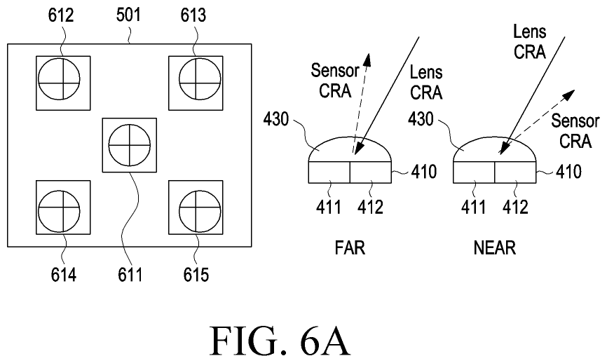

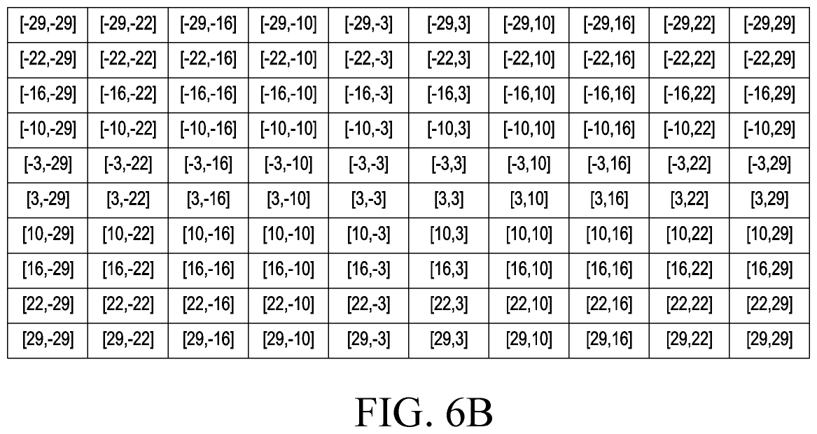

FIG. 5 is a diagram illustrating an example of shading correction in an electronic device according to an embodiment, FIG. 6A is a diagram illustrating an example of an image sensor in camera circuitry according to an embodiment, and FIG. 6B is an example of a lookup table (LUT) including shading correction data according to an embodiment.

Referring to FIG. 5, FIG. 6A, and FIG. 6B, according to an embodiment, the electronic device 101 may obtain an image 501 (e.g., image data) corresponding to an object (e.g., a subject) through the lens 211 of the camera circuitry 200, and display an image (e.g., a preview image) obtained by performing an image processing process on the obtained image 501, on the display 160.

According to an embodiment, the image signal processor 260 (e.g., the processor 120 of FIG. 1) of the camera circuitry 200 may automatically specify an ROI 503 in the image 501 based on a user input or a specified condition, while performing a focus operation, a zoom operation, or a hand shake correction operation. According to an embodiment, the image signal processor 260 may identify the position of the ROI 503 based on the positions of areas divided on (e.g., in the image height) the image sensor 230, and identify the position of the image sensor 230 and/or the lens 211, using at least one sensor (e.g., a gyro sensor or a Hall sensor).

According to an embodiment, before specifying the ROI, the image signal processor 260 may divide an area (e.g., the image height) corresponding to the pixel array 331 of the image sensor 230 into a specified size. For example, the size of each of the divided areas may correspond to the ROI 503 (e.g., the size of the CRA). For example, as illustrated in FIG. 6A, a uniform shake correction effect may be obtained in all directions in a central area 611 of the image 501, and thus no shading or minimal shading occurs, while shading may increase in edge areas 612, 613, 614, and 615 (e.g., some areas in the image height) due to the focus adjustment operation, the zoom operation, or hand shaking.

According to an embodiment, the image signal processor 260 may pre-store shading correction data for all areas divided in the image height of the image sensor 230 in the form of an LUT in the memory 250 (or the memory 130 of FIG. 1) so that it may be used in correcting a shading deviation in a pixel (e.g., between sub-photodiodes) of the ROI, as illustrated in FIG. 6B. According to an embodiment, the image signal processor 260 may control the image stabilizer 240 based on the shading correction data (e.g., coordinate values or movement values that control the position of the lens or the image sensor using OIS) to ensure that the image sensor 230 or the lens 211 is accurately located at a specified position. According to an embodiment, the image signal processor 260 may set, as actuator setting values for shading correction, actuator setting values (e.g., position information (coordinate values) or movement information (movement values) of the image senor 230 or the lens 211 controlled by the actuator) of optimal OIS for all areas (e.g., ROIs of a predetermined size divided from an image (e.g., 400×300 ROIs divided from a 4000×3000 image)) for each position of the actuator of the image stabilizer 240, which are detected using at least one sensor (e.g., a gyro sensor or a Hall sensor), and include the set actuator setting values in the shading correction data. For example, the image signal processor 260 may identify position information (e.g., coordinate values) of the image sensor 230 or position information (e.g., coordinate values) of the lens 211, which is moved by the actuator, in which a shading difference or a pixel gain variance in each area is minimized and/or reduced. The image signal processor 260 may pre-store the shading correction data including the position information (coordinate values) of the image sensor 230 or the lens 211 for CRA alignment of each area, that is, the position information (e.g., actuator setting values) in which a shading difference or a pixel gain variance is minimized and/or reduced, in the form of an LUT (e.g., a 10×10 LUT) in the memory 250, as illustrated in FIG. 6B. The shading correction data may further include other information related to shading correction in addition to the position information in which the shading difference or the pixel gain variance is minimized and/or reduced. For example, since the lens 211 may have a different viewing angle (e.g., CRA) depending on the focus adjustment operation (AF operation), the image signal processor 260 may preset two LUTs for a subject of a flat light source and two positions (e.g., specified points (farthest FAR and nearest NEAR) for auto-focusing) of the AF operation, and perform a fitting operation to correspond to a CRA change at all AF positions. For example, as the micro lens 430 is configured (e.g., designed) to set (fix) the CRA so that shading of pixels may be minimized and/or reduced based on FAR, when the CRA of the lens 211 changes due to the focus adjustment operation, zoom operation, or OIS operation in an imaging environment, the shading deviation may increase. The electronic device 101 may preset a FAR LUT and store it in the memory 250, for use in shading correction, in the case where when focusing on a FAR (farthest) subject by adjusting the vertical position of the lens 211 (e.g., when the sub-photodiode 412 receives light at the CRA of the lens), CRA misalignment at a position other than a point (e.g., optimized point) set for the micro lens 430 increases a shading deviation. The electronic device 101 may preset a NEAR LUT and store it in the memory 250, for use in shading correction, in the case where when focusing on a NEAR (farthest) subject (e.g., when the sub-photodiode 411 receives light at the CRA of the lens), CRA misalignment increases a shading deviation.

According to an embodiment, the image signal processor 260 may identify whether it is necessary to correct shading increased by the focus adjustment operation, the zoom operation, or hand shaking. When the image signal processor 260 identifies that shading correction is required, it may specify the ROI 503 on the image 501 and obtain shading correction data stored in the memory 250 corresponding to the position of the specified ROI 503. The image signal processor 260 may identify position information in which a shading difference or a pixel gain variance is minimized and/or reduced, corresponding to the position of the specified ROI 503, in the shading correction data.

According to an embodiment, the image signal processor 260 may identify a position (e.g., a target movement position) to which the image sensor 230 or the lens 211 is to be moved, based on the position information identified in the shading correction data, and control the actuator of the image stabilizer 240 to move the image sensor 230 or the lens 211 to the position. According to an embodiment, since a first position (e.g., coordinates) 513 of the ROI (a region on an image corresponding to an object of interest) specified on the image 501 (e.g., on coordinates of the image) is changed to a second position 505 due to the movement of the image sensor 230 or the lens 211, the electronic device 101 may correct the changed second position 505 to a third position 507 corresponding to the first position 503. According to an embodiment, the image signal processor 260 may obtain image data of the ROI in which the shading deviation is corrected by the movement of the image sensor 230 or the lens 211. According to an embodiment, the electronic device 101 may display a captured image (e.g., a final captured image or a completely corrected image) on the display 160 or store it in the memory 130.

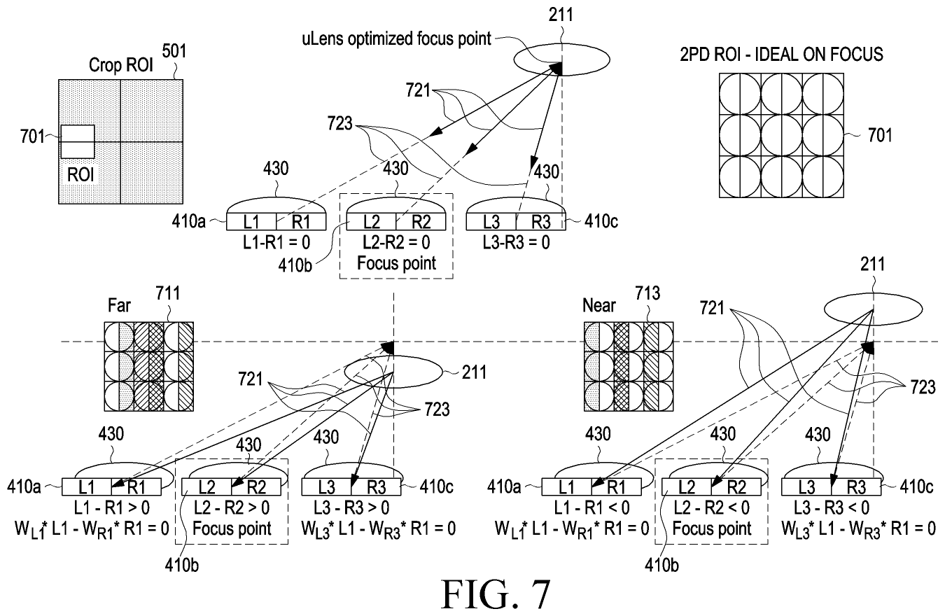

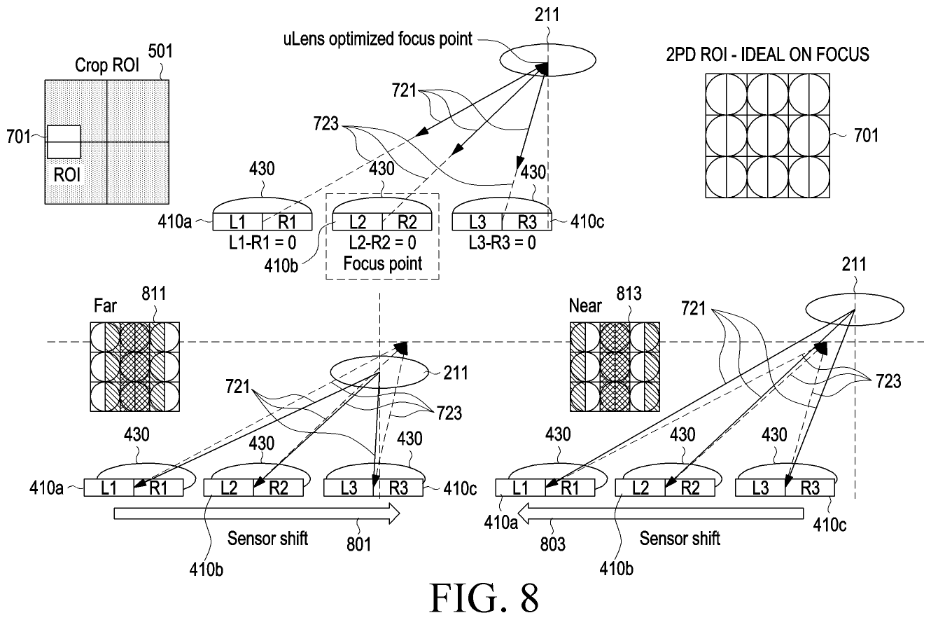

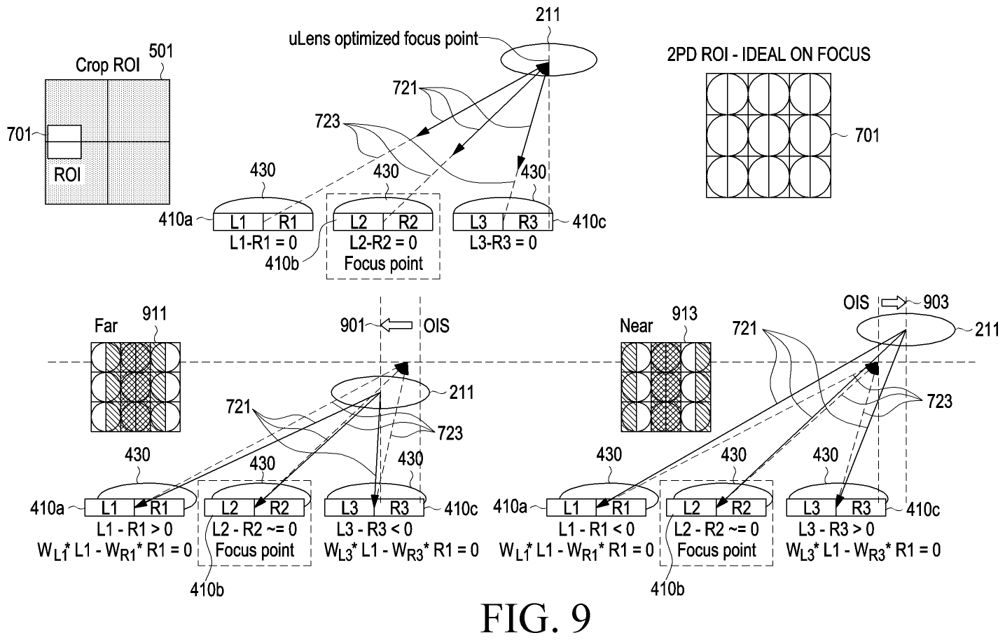

FIG. 7 is a diagram illustrating an example of CRA alignment in camera circuitry of an electronic device according to an embodiment. FIG. 8 is a diagram illustrating an example of a sensor shift operation in camera circuitry of an electronic device according to an embodiment. FIG. 9 is a diagram illustrating an example lens shift operation in camera circuitry of an electronic device according to an embodiment.

Referring to FIGS. 7 and 8, according to an embodiment, the camera circuitry 200 of the electronic device 101 may specify an ROI 701 in the image height of the image 501, and identify unit pixels (e.g., unit photodiodes 410a, 410b, and 410c) of the image sensor 230 at the position of the specified ROI 701. Micro lenses 430 of the image sensor 230 are optimized to minimize and/or reduce shading based on a specific point (e.g., focus of a FAR subject 711). Each of the unit photodiodes 410a, 410b, and 410c may include two or four sub-photodiodes. For example, a first unit photodiode 410a may include two sub-photodiodes L1 and R1. For example, a second unit photodiode 410b may include two sub-photodiodes L2 and R2. For example, a third unit photodiode 410c may include two sub-photodiodes L3 and R3.

According to an embodiment, when the unit pixels (e.g., the unit photodiodes 410a, 410b, and 410c) at the position of the specified ROI 701 are CRA-aligned, the image signal processor 260 of the camera circuitry 200 may identify that shading correction is not required. The CRA alignment of the unit pixels may refer, for example, to a CRA 721 of the lens 211 and a CRA 723 of the image sensor 230 being identical or approximately identical without misalignment. The CRAs may be more misaligned in an out-of-focus state than in an in-focus state. In the out-of-focus case, the image signal processor 260 may correct the shading between sub-photodiodes by moving the position of the image sensor. The CRA misalignment in the in-focus state may be corrected by a method of correcting a photodiode value. The image signal processor 260 may correct an error caused by the method of correcting a photodiode value by moving the position of the image sensor. According to an embodiment, the image signal processor 260 of the camera circuitry 200 may identify that the position of the image sensor 230 or the lens 211 is changed by the actuator included in the image stabilizer 240 due to hand shaking or camera shaking, when performing the focus adjustment operation, the zoom operation, or the hand shake correction operation. The image signal processor 260 may identify the CRA misalignment of the unit pixels (e.g., the unit photodiodes 410a, 410b, and 410c) at the position of the specified ROI 701 due to the change of the position of the image sensor 230 or the lens 211 by the actuator. For example, as illustrated in FIG. 7, the image signal processor 260 may identify the CRA misalignment (e.g., L1-R1>0, L2-R2>0, and L3-R3>0, or L1-R1<0, L2-R2<0, and L3-R3<0) of the unit pixels (e.g., the unit photodiodes 410a, 410b, and 410c) at the position of the specified ROI 701 by the movement of the lens 211 (e.g., adjustment to focusing of a Far subject 711 or adjustment to focusing of a Near subject 713). The image signal processor 260 may identify that the shading deviation between sub-photodiodes (e.g., sub-pixels) of the ROI 701 increases (e.g., a deviation value between L1 and R1 in the ROI 701 is equal to or greater than a threshold and/or a deviation value between L2 and R2 is equal to or greater than the threshold) due to the CRA misalignment of the unit pixels (e.g., the unit photodiodes 410a, 410b, and 410c) at the position of the specified ROI 701.

According to an embodiment, the image signal processor 260 may identify that the lens CRA 721 changes, as the lens 211 moves by the focus adjustment operation, the zoom operation, or the hand shake correction operation during imaging. When the image signal processor 260 identifies that the lens CRA 721 changes by the focus adjustment operation, the zoom operation, or the hand shake correction operation, the image signal processor 260 may minimize and/or reduce a shading deviation caused by mismatch between the sensor CRA 723 and the lens CRA 721 in the ROI 701 (e.g., make the shading deviation less than a specified threshold or minimum value) by performing a sensor shift operation of changing the optical system, that is, changing the position of the image sensor 230 using a sensor shift method, as illustrated in FIG. 8. For example, when the lens CRA 721 is misaligned in the specified ROI 701 due to focusing of the position of the lens 211 on the Far subject, the image signal processor 260 may correct the shading deviation (e.g., between sub-pixels) in the specified ROI 701 by performing a first sensor shift 801 (e.g., moving the image sensor 230) in a direction (e.g., a first direction) in which the sensor CRA 723 of the unit photodiodes 410a, 410b, and 410c of the image sensor 230 is aligned with the lens CRA 721 of the lens 211. The image signal processor 260 may obtain image data of an ROI 811 in which the shading deviation (e.g., between sub-pixels) is corrected through the first sensor shift 801. According to an embodiment, when the lens CRA 721 in the specified ROI 701 is misaligned due to focusing on the Near subject, the image signal processor 260 may perform a second sensor shift 803 (e.g., moving the image sensor 230) in a second direction in which the sensor CRA 723 of the unit photodiodes 410a, 410b, and 410c of the image sensor 230 is aligned with the lens CRA 721 of the lens 211 through the sensor shift 803, thereby correcting the shading deviation in the specified ROI 701. The image signal processor 260 may obtain image data of the ROI 813 in which the shading deviation is corrected through the second sensor shift 803. Through this shading correction, the image signal processor 260 may reduce the loss of a dynamic range and improve noise in the image.

According to an embodiment, when the image signal processor 260 identifies that the lens CRA 721 is changed by the focus adjustment operation, the zoom operation, or the hand shake correction operation, the image signal processor 260 may minimize and/or reduce the shading deviation in the ROI 701 (e.g., make the shading deviation less than the specified threshold or minimum value) by changing the optical system, that is, changing (moving) the position of the lens 211 in a direction in which the sensor CRA 723 of the unit photodiodes 410a, 410b, and 410c and the lens CRA 721 of the lens 211 are aligned, and thus correcting the position (e.g., coordinates) of the ROI 701, as illustrated in FIG. 9. For example, the image signal processor 260 may correct the shading deviation in the specified ROI 701 by changing the position of the lens 211 in the first direction in which the sensor CRA 723 and the lens CRA 721 are matched using OIS, even if the position of the lens 211 is adjusted by focusing of the Far subject and the CRA is misaligned in the specified ROI 701 through a first lens shift 901. The image signal processor 260 may obtain image data of an ROI 911 in which the shading deviation is corrected through the first lens shift 901. According to an embodiment, when the Near subject is focused, the image signal processor 260 may change the position of the lens 211 in a second direction in which the sensor CRA 723 and the lens CRA 721 are aligned using OIS, thereby correcting the shading deviation in the specified ROI 701. The image signal processor 260 may obtain image data of an ROI 913 in which the shading deviation is corrected through the first lens shift 901. Through this shading correction, the image signal processor 260 may reduce the loss of a dynamic range and improve noise in the image.

Accordingly, in an embodiment, the main components of the electronic device have been described through the electronic device 101 of FIGS. 1 and 2. However, in various embodiments, all of the components illustrated in FIGS. 1 and 2 are not essential components, and the electronic device 101 may be implemented with more or fewer components than the illustrated components. The positions of the main components of the electronic device 101 described above with reference to FIGS. 1 and 2 may be changed according to various embodiments.

The disclosure provides an electronic device, method, and non-transitory storage medium for capturing an image, which correct shading caused by an error in alignment between the CRAs of an image sensor and a lens due to a change in the CRA of the lens, when capturing an image.

According to an example embodiment, an electronic device (e.g., the electronic device 101 of FIGS. 1 and 2), a display (e.g., the display module 160 of FIG. 1 and the display 160 of FIG. 3)), a camera assembly including camera circuitry (e.g., the camera module 180 of FIG. 1 and the camera circuitry 180 and 200 of FIG. 2), at least one processor comprising processing circuitry (e.g., the processor 120 of FIG. 1 and the image signal processor 260 of FIGS. 2 and 3), and memory (e.g., the memory 130 of FIG. 1 and the memory 250 of FIG. 2) storing instructions.

According to an example embodiment, the camera assembly may include a lens (e.g., the lens assembly 210 of FIG. 2 and the lens 211 of FIG. 3), an image sensor (e.g., the image sensor 230 of FIGS. 2 and 3) configured to provide an electric signal corresponding to light received through the lens, and an image stabilizer (e.g., the image stabilizer 240 of FIGS. 2 and 3) including an actuator configured to move at least one of the lens or the image sensor for image stabilization.

According to an example embodiment, the image sensor may include a plurality of unit photodiodes (e.g., the unit photodiodes 410 of FIG. 4A), each including a plurality of sub-photodiodes (e.g., the sub-photodiodes 411 and 412 of FIG. 4A), and a plurality of micro lenses corresponding to the plurality of unit photodiodes, respectively, and the plurality of sub-photodiodes included in one unit photodiode may correspond to one micro lens.

According to an embodiment, at least one processor individually or collectively, may be configured to execute the instructions and to cause the electronic device to: obtain an image corresponding to a subject using the image sensor, obtain, from the memory, specified shading correction data for shading correction of a first ROI specified within the image, wherein the shading correction data includes position information set to match a CRA of the image sensor or a CRA of the lens to a specified CRA, based on the shading correction data, identify a movement position of the image sensor to correct a shading deviation between first sub-photodiodes corresponding respectively to a plurality of first micro lenses arranged in a first area corresponding to the first ROI in an image height of the image sensor, based on the movement position, control the actuator to move a position of the image sensor, and obtain, using the image sensor, first image data of the first ROI in which the shading deviation between the first sub-photodiodes is corrected.

According to an example embodiment, the position information included the shading correction data may be position information in which the shading deviation between the plurality of sub-photodiodes is identified as less than a specified minimum value, and the position information included in the shading correction data may include at least one of position information of the image sensor or position information of the lens, which is controlled by the actuator.

According to an example embodiment, the at least one processor individually or collectively, may be configured to cause the electronic device to: before obtaining the image, divide areas of a specified size in the image height of the image sensor, identify at least one of the position information of the image sensor or the position information of the lens in each of the divided areas, set the shading correction data including at least one of the position information of the image sensor or the position information of the lens, and store the shading correction data in the memory.

According to an example embodiment, the specified CRA may be set so that the shading deviation is less than the minimum value, and the specified CRA may be an inflow angle of light in which the CRA of the lens and the CRA of the image sensor are aligned without misalignment.

According to an example embodiment, at least one processor individually or collectively, may be configured to cause the electronic device to, based on the shading correction data, identify a movement position of the lens, and based on the movement position of the lens, control the actuator to move the lens along a specified axis.

According to an example embodiment, at least one processor individually or collectively, may be configured to cause the electronic device to: based on receiving the image while performing a hand shake correction operation, a focus adjustment operation or a zoom operation, identify that the inflow angle of light received through the lens and the plurality of micro lenses is outside the specified CRA, and in order to correct the shading deviation caused in the first ROI due to the inflow angle of light being outside the specified CRA, control the actuator to move the image sensor in a direction in which the CRA of the lens and the CRA of the image sensor are aligned without misalignment based on the movement position of the image sensor.

According to an example embodiment, an electronic device (e.g., the electronic device 101 of FIGS. 1 and 2) may include a display (e.g., the display module 160 of FIG. 1 and the display 160 of FIG. 3), a camera assembly including camera circuitry (e.g., the camera module 180 of FIG. 1 and the camera circuitry 200 of FIG. 2), at least one processor comprising processing circuitry (e.g., the processor 120 of FIG. 1 and the image signal processor 260 of FIGS. 2 and 3), and memory (e.g., the memory 130 of FIG. 1 and the memory 250 of FIG. 2) storing instructions.

According to an example embodiment, the camera assembly may include a lens (e.g., the lens assembly 210 of FIG. 2 and the lens 211 of FIG. 3), an image sensor (e.g., the image sensor 230 of FIGS> 2 and 3) configured to provide an electric signal corresponding to light received through the lens, and an image stabilizer (e.g., the image stabilizer 240 of FIGS. 2 and 3) including an actuator configured to move at least one of the lens or the image sensor for image stabilization.

According to an example embodiment, the image sensor may include a plurality of unit photodiodes (e.g., the unit photodiodes 410 of FIG. 4A, each including a plurality of sub-photodiodes (e.g., the sub-photodiodes 411 and 412 of FIG. 4A), and a plurality of micro lenses corresponding to the plurality of unit photodiodes, respectively. The plurality of sub-photodiodes included in one unit photodiode may correspond to one micro lens.

According to an example embodiment, at least one processor individually or collectively, may be configured to cause the electronic device to: obtain an image corresponding to a subject using the image sensor, obtain, from the memory, specified shading correction data for shading correction of a first ROI specified within the image, wherein the shading correction data includes position information set to match a CRA of the image sensor or a CRA of the lens to a specified CRA, based on the shading correction data, identify a target movement position of the lens to correct a shading deviation between first sub-photodiodes corresponding respectively to a plurality of first micro lenses arranged in a first area corresponding to the first ROI in an image height of the image sensor, based on the target movement position of the lens, control the actuator to move a position of the lens, and obtain, using the image sensor, second image data of the first ROI in which the shading deviation is corrected by the movement of the lens.

According to an example embodiment, the position information included the shading correction data may include position information in which the shading deviation between the plurality of sub-photodiodes is identified as less than a specified minimum value, and the position information included in the shading correction data may include at least one of position information of the image sensor or position information of the lens, which is controlled by the actuator.

According to an example embodiment, the specified CRA may be set so that the shading deviation is less than the minimum value, and the specified CRA may be an inflow angle of light in which the CRA of the lens and the CRA of the image sensor are aligned without misalignment.

According to an example embodiment, at least one processor individually or collectively, may be configured to cause the electronic device to: based on receiving the image while performing a hand shake correction operation, a focus adjustment operation or a zoom operation, identify that the inflow angle of light received through the lens and the plurality of micro lenses is outside the specified CRA, and in order to correct the shading deviation caused in the first ROI due to the inflow angle of light being outside the specified CRA, control the actuator to move the lens in a direction in which the CRA of the lens and the CRA of the image sensor are aligned without misalignment based on the target movement position of the lens.

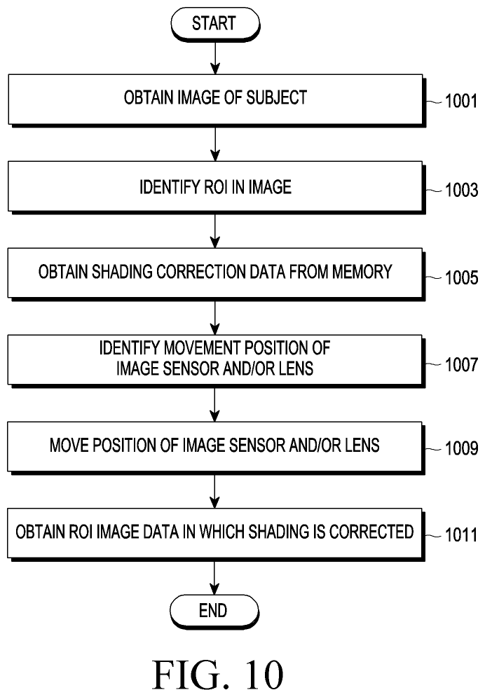

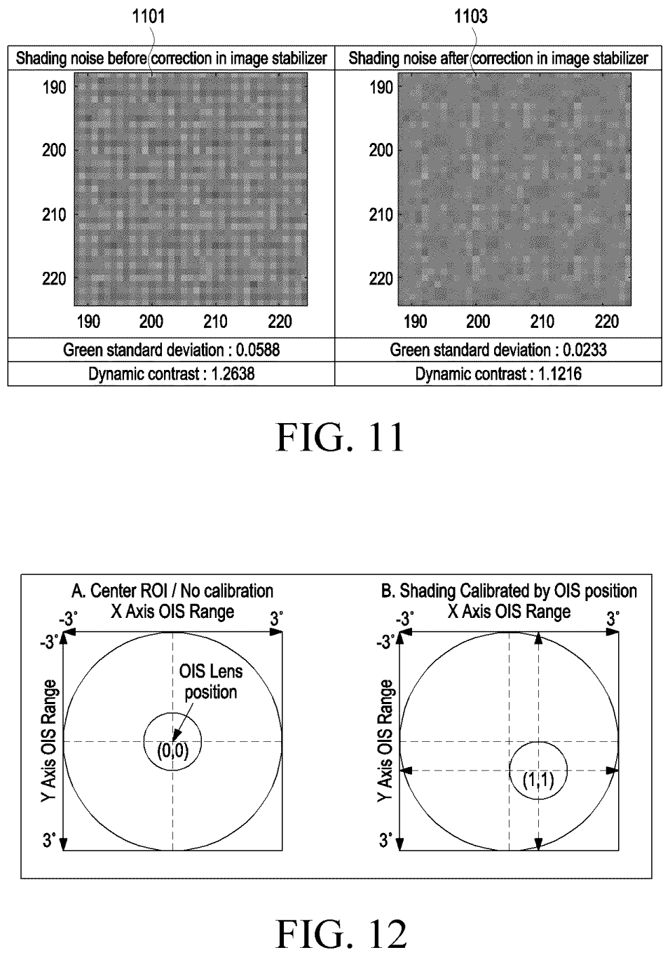

FIG. 10 is a flowchart illustrating an example method of operating an electronic device according to an embodiment, and FIG. 11 is a diagram illustrating an example of shading correction in a method of operating an electronic device according to an embodiment. In the following example embodiment, each operation may be performed sequentially, but not necessarily. For example, the order of each operation may be changed, and at least two operations may be performed in parallel.

Referring to FIG. 10, in operation 1001, an electronic device (e.g., the electronic device 101 of FIGS. 1 and 2) according to an embodiment may obtain image data corresponding to an object (e.g., a subject) through the lens 211 of camera circuitry (e.g., the camera module 180 of FIG. 1 and the camera circuitry 200 of FIG. 2), and display an image (e.g., a preview image) for the obtained image data on a display (e.g., the display module 160 of FIG. 1 and the display 160 of FIG. 3).

In operation 1003, the electronic device may automatically specify (e.g., identify) an ROI in the image based on a user input or a specified condition by an image signal processor (e.g., the processor 120 of FIG. 1 and the image signal processor 260 of FIG. 2) of the camera circuitry.

In operation 1005, the electronic device may obtain shading correction data in the specified ROI from memory (e.g., the memory 130 of FIG. 1 and the memory 250 of FIG. 2). The electronic device may identify shading correction data corresponding to an image height corresponding to the specified ROI. The shading correction data may be pre-specified and stored in the memory in the form of a LUT, before performing the operation. The shading correction data may be set to correct shading (e.g., a shading deviation between sub-photodiodes) caused in the specified ROI due to an inflow angle of light received through a plurality of micro lenses included in an image sensor being outside a specified CRA. The shading correction data may include information indicating a position at which a shading deviation between sub-pixels (e.g., sub-photodiodes) included in each of a plurality of unit pixels (e.g., unit photodiodes) is minimized and/or reduced (e.g., the shading deviation is less than a specified threshold or minimum value) (e.g., position information (coordinate values minimizing and/or reducing the variance of a pixel gain measured to correct shading)). The shading correction data may include position information (e.g., position information of the image sensor and/or position information of the lens) set so that the CRA of the image sensor (e.g., sensor CRA) or the CRA of the lens (e.g., lens CRA) matches a specified CRA.

In operation 1007, the electronic device may identify a movement position (e.g., a position to which a movement is to be made or a shift amount) for moving the image sensor 230 and/or the lens 211 based on the shading correction data. The electronic device may identify the position of an ROI based on the positions of areas divided in the image height of the image sensor (e.g., the image sensor 230 of FIG. 2) by the image signal processor, and identify the position (e.g., the position of the actuator for image stabilization) of the image sensor 230 and/or the lens 211, using at least one sensor (e.g., a gyro sensor or a Hall sensor). The electronic device may identify position information in which a shading deviation is minimized and/or reduced (e.g., a shading deviation is less than the specified threshold or minimum value) (e.g., position information in which the deviation of a pixel gain measured for shading correction is minimized and/or reduced), included in the shading correction data, as a target movement position. In operation 1007, the electronic device may identify the movement position to which the image sensor 230 and/or the lens 211 is to moved based on the pre-specified shading correction data.

In operation 1009, the electronic device may control the image stabilizer (e.g., the actuator included in the camera circuitry) to move the position of the image sensor and/or the position of the lens based on the identified movement position. In operation 1009, when moving the position of the image sensor 230, the electronic device may control the image stabilizer (e.g., the actuator) to move the position of the image sensor using a sensor shift method. In operation 1009, when moving the position of the lens 211, the electronic device may control the image stabilizer (e.g., the actuator) to move the lens 211 to the identified target movement position of the lens 211 in a lens shift method of OIS. According to an embodiment, as the image sensor and/or the lens is moved, the electronic device may correct the position of the specified ROI.

In operation 1011, the electronic device may obtain image data of the ROI in which the shading deviation is corrected (e.g., the shading is reduced) by CRA alignment achieved by the movement of the image sensor and/or the lens. For example, when the shading is not corrected in the specified ROI, the ROI may have an increased shading deviation (e.g., a green standard deviation: 0.0588) between the sub-pixels (e.g., sub-photodiodes) included in unit pixels, as in a pre-correction ROI image 1101 in FIG. 11. When shading correction is performed on the specified ROI through the operation method of FIG. 10 described above, the ROI may have a reduced shading deviation (e.g., a green standard deviation) (e.g., a green standard deviation: 0.0233) between the sub-pixels (e.g., sub-photodiodes) included in the unit pixels, as in a post-correction ROI image 1103 in FIG. 11.

The electronic device according to an embodiment may move the position of the image sensor (e.g., the image sensor 230 of FIGS. 2 and 3) and/or the lens (e.g., the lens 211 of FIG. 3) based on pre-specified shading correction data in the same manner as the operation method of FIG. 10 described above, and obtain ROI image data with shading corrected therein according to the movement of the position of the image sensor and/or the lens.

When the shading correction is completed in the image through the operation method of FIG. 10 described above, the electronic device according to an embodiment may perform an image preprocessing operation, and then capture an image of the subject with improved quality according to a capture request (e.g., input of a capture button). The electronic device 101 may display the captured image (e.g., a final captured image or a completely corrected image) on the display 160 or store it in the memory 130.

Before performing the operation method of FIG. 10 as described above, the electronic device according to an embodiment may preset (e.g., specify or measure) shading correction data for all areas divided in the image height of the image sensor, for shading correction, and store it in the memory 250 (or the memory 130 of FIG. 1) in the form of an LUT. According to an embodiment, to preset the shading correction data, the electronic device may control the image stabilizer so that the image sensor and/or the lens is accurately disposed at a specified position (e.g., a position specified during design). According to an embodiment, the electronic device may identify an image of an area that minimizes and/or reduces a shading deviation or the variance of a pixel gain), for each area, and identify the position of the actuator corresponding to the identified image of the area. The electronic device may store shading correction data including the position of the actuator for CRA alignment, for each area (e.g., position information in which the variance of a pixel gain measured for shading correction is minimized and/or reduced) in the form of an LUT in the memory. The shading correction data may further include other information related to shading correction in addition to the position information in which the shading deviation or the pixel gain variance is minimized and/or reduced. For example, since the lens 211 may change the viewing angle (e.g., CRA) depending on the focus adjustment operation (AF operation), the electronic device may configure two LUTs for a subject of a flat light source and two positions Farthest and Nearest of the AF operation, and perform an appropriate fitting operation to cope with CRA changes at all AF positions.

When remosaicing an image (e.g., raw image data), the electronic device according to an embodiment may perform shading correction by specifying a cropped image as an ROI using a remosaic zoom operation and performing shading correction through the operation method of FIG. 10 described above.

FIG. 12 is a diagram illustrating an example of shading correction according to an embodiment.

The electronic device according to an embodiment may perform a shading correction operation, while performing hand shake correction (OIS). When the electronic device performs the shading correction operation while performing the hand shake correction (OIS), a lens movement range for OIS of the image stabilizer may be limited as the lens is moved for shading correction, as illustrated in FIG. 12. Accordingly, the electronic device may perform the shading correction while reducing an OIS operating range (e.g., margin). As illustrated in FIG. 12, the lens may be moved in all directions by a specified range in a center ROI or in a state where shading correction is not performed. Accordingly, a uniform shake correction effect may be obtained in all directions in the center ROI or in the state where shading correction is not performed.

According to an embodiment, when a flare occurs in the entire image, the electronic device may adjust the position of the lens using OIS because light is incident at an angle outside a specified CRA of the lens.

According to an embodiment, when OIS correction is not performed, the electronic device may perform only the shading correction operation.

According to an embodiment, the electronic device may perform only the shading correction operation while performing the focus adjustment operation or the zoom operation (e.g., digital zoom), without performing OIS correction.

According to an example embodiment, a method of operating an electronic device (e.g., the electronic device 101 of FIGS. 1 and 2) may include: obtaining an image corresponding to a subject using an image sensor (e.g., the image sensor 230 of FIGS. 2 and 3) included in a camera assembly (e.g., a camera assembly including the camera module 180 and the camera circuitry 200 of FIG. 1) of the electronic device.

According to an example embodiment, the method may include: obtaining, from memory (e.g., the memory 130 of FIG. 1 and the memory 250 of FIG. 2) of the electronic device, pre-specified shading correction data for shading correction of a first ROI specified within the image. According to an embodiment, the shading correction data may include position information set to match a CRA of the image sensor or a CRA of a lens to a specified CRA.

According to an example embodiment, the method may include, based on the shading correction data, identifying a movement position of the image sensor to correct a shading deviation between first sub-photodiodes (e.g., the sub-photodiodes 411 and 412 of FIG. 4A) corresponding respectively to a plurality of first micro lenses (e.g., the micro lens 430 of FIG. 4A) arranged in a first area corresponding to the first ROI in an image height of the image sensor.

According to an example embodiment, the method may include, based on the movement position, controlling an actuator included in an image stabilizer (e.g., the image stabilizer 240 of FIGS. 2 and 3) of the camera assembly to move a position of the image sensor.

According to an example embodiment, the method may include obtaining, using the image sensor, first image data of the first ROI in which the shading deviation between the first sub-photodiodes is corrected.

According to an example embodiment, in the shading correction data, the shading deviation between the plurality of sub-photodiodes is identified as less than a minimum value, and the shading correction data may include at least one of position information of the image sensor or position information of the lens, which is controlled by the actuator.

According to an example embodiment, the method may further include: before obtaining the image, dividing areas of a specified size in the image height of the image sensor, identifying at least one of the position information of the image sensor or the position information of the lens in each of the divided areas, setting the shading correction data including at least one of the position information of the image sensor or the position information of the lens, and storing the shading correction data in the memory.

According to an example embodiment, the specified CRA may be set so that the shading deviation is less than the minimum value, and the specified CRA may be an inflow angle of light in which the CRA of the lens and the CRA of the image sensor are aligned without misalignment.

According to an example embodiment, the method may further include, based on the shading correction data, identifying a movement position of the lens, and based on the movement position of the lens, controlling the actuator to move the lens along a specified axis.

According to an example embodiment, the method may include: based on receiving the image while performing a hand shake correction operation, a focus adjustment operation or a zoom operation, identifying that the inflow angle of light received through the lens and the plurality of micro lenses is outside the specified CRA, and in order to correct the shading deviation caused in the first ROI due to the inflow angle of light being outside the specified CRA, controlling the actuator to move the image sensor in a direction in which the CRA of the lens and the CRA of the image sensor are aligned without misalignment based on the movement position of the image sensor.

According to an example embodiment, in a non-transitory computer-readable storage medium storing at least one program, the at least one program may include instructions that, when executed by at least one processor, comprising processing circuitry, individually and/or collectively, (e.g., the processor 120 of FIG. 1 and the image signal processor 260 of FIGS. 2 and 3) of an electronic device (e.g., the electronic device 101 of FIGS. 1 and 2), cause the electronic device to: obtain an image corresponding to a subject using an image sensor (e.g., the image sensor 230 of FIGS. 2 and 3) included in a camera assembly of the electronic device, obtain, from memory (e.g., the memory 130 of FIG. 1 and the memory 250 of FIG. 2) of the electronic device, specified shading correction data for shading correction of a first ROI specified within the image, wherein the shading correction data includes position information set to match a CRA of the image sensor or a CRA of a lens to a specified CRA, based on the shading correction data, identify a movement position of the image sensor to correct a shading deviation between first sub-photodiodes corresponding respectively to a plurality of first micro lenses arranged in a first area corresponding to the first ROI in an image height of the image sensor, based on the movement position, control an actuator included in an image stabilizer (e.g., the image stabilizer 240 of FIGS. 2 and 3) of the camera assembly to move a position of the image sensor, and obtain, using the image sensor, first image data of the first ROI in which the shading deviation between the first sub-photodiodes is corrected.

According to an example embodiment, the specified CRA may be set so that the shading deviation is less than the minimum value, and the specified CRA may be an inflow angle of light in which the CRA of the lens and the CRA of the image sensor are aligned without misalignment.

According to an example embodiment, the at least one program may include instructions that, when executed by at least one processor of the electronic device, cause the electronic device to, based on the shading correction data, identify a target movement position of the lens, and based on the target movement position of the lens, control the actuator to move the lens along a specified axis.

According to an example embodiment, the at least one program may include instructions that, when executed by at least one processor of the electronic device, cause the electronic device to: based on receiving the image while performing a hand shake correction operation, a focus adjustment operation or a zoom operation, identify that the inflow angle of light received through the lens and the plurality of micro lenses is outside the specified CRA, and in order to correct the shading deviation caused in the first ROI due to the inflow angle of light being outside the specified CRA, control the actuator to move the image sensor in a direction in which the CRA of the lens and the CRA of the image sensor are aligned without misalignment based on the movement position of the image sensor.

According to an example embodiment of the disclosure, based on the CRA of a lens changing due to a focus adjustment operation, a zoom operation, or an OIS operation, an electronic device may minimize and/or reduce a shading deviation between sub-photodiodes (e.g., a shading deviation between pixels) (e.g., so that the shading deviation is less than a specified minimum value) by changing an optical system itself with a sensor shift or OIS, thereby improving a focus detection capability and improving the optical/electrical image stabilization and subject tracking performance of camera circuitry. According to an embodiment of the disclosure, when the electronic device utilizes a phase detection pixel itself as a pixel of an image through remosaic, the electronic device may improve the deterioration of image quality caused by shading. In addition, various effects that may be directly or indirectly recognized through the disclosure may be provided. The effects that may be obtained from the disclosure are not limited to the effects mentioned above, and other effects that are not mentioned may be clearly understood by those skilled in the art from the following description.

The various example embodiments of the disclosure are presented for the purpose of describing and understanding the disclosed technical contents and do not limit the scope of the technology of the disclosure. Therefore, the scope of the disclosure should be interpreted to include all modifications or various embodiments based on the technical idea of the disclosure. It will also be understood that any of the embodiment(s) described herein may be used in conjunction with any other embodiment(s) described herein.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases. As used herein, such terms as “1st” and “2nd”, or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with”, “coupled to”, “connected with”, or “connected to” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, logic, logic block, part, or circuitry. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

What is claimed is:

1. An electronic device comprising:
a display;
a camera assembly including camera circuitry;
at least one processor comprising processing circuitry; and
memory storing instructions,
wherein the camera assembly comprises:
a lens;
an image sensor configured to provide an electric signal corresponding to light received through the lens; and
an image stabilizer including an actuator configured to move at least one of the lens or the image sensor for image stabilization,
wherein the image sensor comprises:
a plurality of unit photodiodes, each including a plurality of sub-photodiodes; and
a plurality of micro lenses corresponding to the plurality of unit photodiodes, respectively, wherein the plurality of sub-photodiodes included in one unit photodiode correspond to one micro lens, and
wherein the instructions, when executed by the at least one processor individually or collectively, cause the electronic device to:
obtain an image corresponding to a subject using the image sensor;
obtain, from the memory, specified shading correction data for shading correction of a first region of interest (ROI) specified within the image, wherein the shading correction data includes position information set to match a chief ray angle of the image sensor or a chief ray angle of the lens to a specified chief ray angle;
based on the shading correction data, identify a movement position of the image sensor to correct a shading deviation between first sub-photodiodes corresponding respectively to a plurality of first micro lenses arranged in a first area corresponding to the first ROI in an image height of the image sensor;
based on the movement position, control the actuator to move a position of the image sensor; and
obtain, using the image sensor, first image data of the first ROI in which the shading deviation between the first sub-photodiodes is corrected.

2. The electronic device of claim 1, wherein the position information included the shading correction data includes position information in which the shading deviation between the plurality of sub-photodiodes is specified to be less than a minimum value, and
wherein the position information included in the shading correction data includes at least one of position information of the image sensor or position information of the lens, controlled by the actuator.

3. The electronic device of claim 1, wherein the instructions, when executed by the at least one processor individually or collectively, cause the electronic device to:
before obtaining the image, divide areas of a specified size in the image height of the image sensor,
identify at least one of the position information of the image sensor or the position information of the lens in each of the divided areas,
set the shading correction data including at least one of the position information of the image sensor or the position information of the lens, and
store the shading correction data in the memory.

4. The electronic device of claim 1, wherein the specified chief ray angle is set so that the shading deviation is less than the minimum value, and
wherein the specified chief ray angle includes an inflow angle of light in which the chief ray angle of the lens and the chief ray angle of the image sensor are aligned without misalignment.

5. The electronic device of claim 1, wherein the instructions, when executed by the at least one processor individually or collectively, cause the electronic device to:
based on the shading correction data, identify a movement position of the lens, and
based on the movement position of the lens, control the actuator to move the lens along a specified axis.

6. The electronic device of claim 1, wherein the instructions, when executed by the at least one processor individually or collectively, cause the electronic device to:
based on receiving the image while performing a hand-shake correction operation, a focus adjustment operation or a zoom operation, identify that the inflow angle of light received through the lens and the plurality of micro lenses is outside the specified chief ray angle, and
to correct the shading deviation caused in the first ROI due to the inflow angle of light being outside the specified chief ray angle, control the actuator to move the image sensor in a direction in which the chief ray angle of the lens and the chief ray angle of the image sensor are aligned without misalignment based on the movement position of the image sensor.

7. A method of operating an electronic device, comprising:
obtaining an image corresponding to a subject using an image sensor included in a camera assembly of the electronic device;
obtaining, from memory of the electronic device, specified shading correction data for shading correction of a first region of interest (ROI) specified within the image, wherein the shading correction data includes position information set to match a chief ray angle of the image sensor or a chief ray angle of a lens to a specified chief ray angle;
based on the shading correction data, identifying a movement position of the image sensor to correct a shading deviation between first sub-photodiodes corresponding respectively to a plurality of first micro lenses arranged in a first area corresponding to the first ROI in an image height of the image sensor;
based on the movement position, controlling an actuator included in an image stabilizer of the camera assembly to move a position of the image sensor; and
obtaining, using the image sensor, first image data of the first ROI in which the shading deviation between the first sub-photodiodes is corrected.

8. The method of claim 7, wherein the position information included the shading correction data includes position information in which the shading deviation between the plurality of sub-photodiodes is specified to be less than a minimum value, and
wherein the position information included in the shading correction data includes at least one of position information of the image sensor or position information of the lens, controlled by the actuator.

9. The method of claim 7, further comprising:
before obtaining the image, dividing areas of a specified size in the image height of the image sensor;
identifying at least one of the position information of the image sensor or the position information of the lens in each of the divided areas;
setting the shading correction data including at least one of the position information of the image sensor or the position information of the lens; and
storing the shading correction data in the memory.

10. The method of claim 7, wherein the specified chief ray angle is set so that the shading deviation is less than the minimum value, and
wherein the specified chief ray angle includes an inflow angle of light in which the chief ray angle of the lens and the chief ray angle of the image sensor are aligned without misalignment.

11. The method of claim 7, further comprising:
based on the shading correction data, identifying a movement position of the lens; and
based on the movement position of the lens, controlling the actuator to move the lens along a specified axis.

12. The method of claim 7, comprising:
based on receiving the image while performing a hand shake correction operation, a focus adjustment operation or a zoom operation, identifying that the inflow angle of light received through the lens and the plurality of micro lenses is outside the specified chief ray angle; and
to correct the shading deviation caused in the first ROI due to the inflow angle of light being outside the specified chief ray angle, controlling the actuator to move the image sensor in a direction in which the chief ray angle of the lens and the chief ray angle of the image sensor are aligned without misalignment based on the movement position of the image sensor.

13. A non-transitory computer-readable storage medium storing at least one program including instructions that, when executed by at least one processor, comprising processing circuitry, individually and/or collectively, of an electronic device, cause the electronic device to:
obtain an image corresponding to a subject using an image sensor included in a camera assembly of the electronic device;
obtain, from memory of the electronic device, specified shading correction data for shading correction of a first region of interest (ROI) specified within the image, wherein the shading correction data includes position information set to match a chief ray angle of the image sensor or a chief ray angle of a lens to a specified chief ray angle;
based on the shading correction data, identify a movement position of the image sensor to correct a shading deviation between first sub-photodiodes corresponding respectively to a plurality of first micro lenses arranged in a first area corresponding to the first ROI in an image height of the image sensor;
based on the movement position, control an actuator included in an image stabilizer of the camera assembly to move a position of the image sensor; and
obtain, using the image sensor, first image data of the first ROI in which the shading deviation between the first sub-photodiodes is corrected.

14. The non-transitory computer-readable storage medium of claim 13, wherein the specified chief ray angle is set so that the shading deviation is less than a minimum value, and
wherein the specified chief ray angle includes an inflow angle of light in which the chief ray angle of the lens and the chief ray angle of the image sensor are aligned without misalignment.

15. The non-transitory computer-readable storage medium of claim 13, wherein the at least one program includes instructions that, when executed by at least one processor, individually and/or collectively, of the electronic device, cause the electronic device to:
based on the shading correction data, identify a target movement position of the lens; and
based on the target movement position of the lens, control the actuator to move the lens along a specified axis.

16. The non-transitory computer-readable storage medium of claim 13, wherein the at least one program includes instructions that, when executed by at least one processor, individually and/or collectively, of the electronic device, cause the electronic device to:
based on receiving the image while performing a hand shake correction operation, a focus adjustment operation or a zoom operation, identify that the inflow angle of light received through the lens and the plurality of micro lenses is outside the specified chief ray angle; and
to correct the shading deviation caused in the first ROI due to the inflow angle of light being outside the specified chief ray angle, control the actuator to move the image sensor in a direction in which the chief ray angle of the lens and the chief ray angle of the image sensor are aligned without misalignment based on the movement position of the image sensor.

17. An electronic device comprising:
a display;
a camera assembly including camera circuitry;
at least one processor, comprising processing circuitry; and
memory storing instructions,
wherein the camera assembly comprises:
a lens;
an image sensor configured to provide an electric signal corresponding to light received through the lens; and
an image stabilizer including an actuator configured to move at least one of the lens or the image sensor for image stabilization,
wherein the image sensor comprises:
a plurality of unit photodiodes, each including a plurality of sub-photodiodes; and
a plurality of micro lenses corresponding to the plurality of unit photodiodes, respectively, wherein the plurality of sub-photodiodes included in one unit photodiode correspond to one micro lens, and
wherein the instructions, when executed by the at least one processor individually or collectively, cause the electronic device to:
obtain an image corresponding to a subject using the image sensor;
obtain, from the memory, specified shading correction data for shading correction of a first region of interest (ROI) specified within the image, wherein the shading correction data includes position information set to match a chief ray angle of the image sensor or a chief ray angle of the lens to a specified chief ray angle;
based on the shading correction data, identify a target movement position of the lens to correct a shading deviation between first sub-photodiodes corresponding respectively to a plurality of first micro lenses arranged in a first area corresponding to the first ROI in an image height of the image sensor;
based on the target movement position of the lens, control the actuator to move a position of the lens; and
obtain, using the image sensor, second image data of the first ROI in which the shading deviation is corrected by the movement of the lens.

18. The electronic device of claim 17, wherein the position information included the shading correction data includes position information in which the shading deviation between the plurality of sub-photodiodes is specified to be less than a minimum value, and
wherein the position information included in the shading correction data includes at least one of position information of the image sensor or position information of the lens, controlled by the actuator.

19. The electronic device of claim 17, wherein the specified chief ray angle is set so that the shading deviation is less than the minimum value, and
wherein the specified chief ray angle includes an inflow angle of light in which the chief ray angle of the lens and the chief ray angle of the image sensor are aligned without misalignment.

20. The electronic device of claim 17, wherein the instructions, when executed by the at least one processor individually or collectively, cause the electronic device to:
based on receiving the image while performing a hand shake correction operation, a focus adjustment operation or a zoom operation, identify that the inflow angle of light received through the lens and the plurality of micro lenses is outside the specified chief ray angle, and
to correct the shading deviation caused in the first ROI due to the inflow angle of light being outside the specified chief ray angle, control the actuator to move the lens in a direction in which the chief ray angle of the lens and the chief ray angle of the image sensor are aligned without misalignment based on the target movement position of the lens.
